(19) United States
(12) Patent Application Publication
(10) Pub. No.: US 2023/0215709 A1
(43) Pub. Date: Jul. 6, 2023

(54) REMOTE PLASMA UNIT AND SUBSTRATE PROCESSING APPARATUS INCLUDING REMOTE PLASMA

(71) Applicant: ASM IP Holding B.V., Almere (NL)

(72) Inventor: Zhikai Miao, Yokohama-shi (JP)

(21) Appl. No.: 18/149,125

(22) Filed: Jan. 2, 2023

Related U.S. Application Data
(60) Provisional application No. 63/296,598, filed on Jan. 5, 2022.

(51) Int. Cl. H01J 37/32; C23C 16/44

(52) U.S. Cl. CPC H01J 37/32862; H01J 37/3288; C23C 16/4405

(57) ABSTRACT

A substrate processing apparatus is disclosed. Exemplary substrate processing apparatus includes a reaction chamber; a remote plasma unit; a cleaning gas lines configured to fluidly couple the remote plasma unit to the reaction chambers ; and a chamber liner disposed in a sidewall of the reaction chamber; wherein the cleaning gas line is connected to the sidewall of the reaction chamber through a cleaning gas opening; wherein the chamber liner is provided with a plurality of holes, being fluidly coupled to the cleaning gas opening.

### CROSS-REFERENCE TO RELATED APPLICATIONS

This application claims priority to U.S. Provisional Patent Application Ser. No. 63/296,598 filed Jan. 5, 2022 titled REMOTE PLASMA UNIT AND SUBSTRATE PROCESSING APPARATUS INCLUDING REMOTE PLASMA, the disclosure of which is hereby incorporated by reference in its entirety.

### FIELD OF INVENTION

The present disclosure relates generally to a remote plasma unit. More particularly, exemplary embodiments of the present disclosure relate to a remote plasma unit and a substrate processing apparatus including a remote plasma unit.

### BACKGROUND OF THE DISCLOSURE

After deposition steps have been performed in a reaction chamber, the reaction chamber may need cleaning to remove undesirable deposition residues that may have formed on the chamber wall. One approach for cleaning the reaction chamber is to use a remote plasma unit (RPU). An exemplary substrate processing apparatus with the RPU is disclosed in US Patent application publication no. US2021/0071296, which is hereby incorporated by reference.

Remote plasma cleaning is a cleaning technique where utilizing a remote plasma source to create a plasma and reactive radicals outside the reaction chamber. There is a need to clean the reaction chamber evenly. The created plasma and reactive radicals may assist in cleaning the reaction chamber evenly.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a reaction chamber; a remote plasma unit; a cleaning gas lines configured to fluidly couple the remote plasma unit to the reaction chambers ; and a chamber liner disposed in a sidewall of the reaction chamber; wherein the cleaning gas line is connected to the sidewall of the reaction chamber through a cleaning gas opening; wherein the chamber liner is provided with a plurality of holes, being fluidly coupled to the cleaning gas opening.

In various embodiments, the holes may be equally spaced on the chamber liner.

In various embodiments, the substrate processing apparatus may further comprise a susceptor positioned within the reaction chamber to be constructed and arranged to support a substrate.

In various embodiments, the substrate processing apparatus may further comprise a shower plate to be constructed and arranged to face the susceptor.

In various embodiments, the substrate processing apparatus may further comprise a second cleaning line disposed between the remote plasma unit and the shower plate.

In various embodiments, the second cleaning gas line may be provided with a process gas line to supply a process gas to the reaction chamber through the shower plate.

In various embodiments, a substrate processing apparatus may comprise a reaction chamber; a remote plasma unit; a cleaning gas lines configured to fluidly couple the remote plasma unit to the reaction chambers; a chamber liner disposed in a sidewall of the reaction chamber; and a gap provided between a bottom of the reaction chamber and a bottom of the chamber liner, wherein the cleaning gas line is connected to the sidewall of the reaction chamber through a cleaning gas opening; wherein the gap configured to fluidly couple the cleaning gas opening.

In various embodiments, the substrate processing apparatus may further comprise a susceptor positioned within the reaction chamber to be constructed and arranged to support a substrate.

In various embodiments, the substrate processing apparatus may further comprise a shower plate to be constructed and arranged to face the susceptor.

In various embodiments, the substrate processing apparatus may further comprise a second cleaning line disposed between the remote plasma unit and the shower plate.

In various embodiments, the second cleaning gas line may be provided with a process gas line to supply a process gas to the reaction chamber through the shower plate.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic plan view of a semiconductor processing apparatus with dual chamber modules usable in an embodiment of the present invention.

FIG. 2 is a schematic cross-sectional view of a dual chamber module in an embodiment of the present invention.

FIG. 3 is a schematic cross-sectional view of a reaction chamber in an embodiment of the present invention.

FIG. 4 is a schematic cross-sectional view of a reaction chamber in another embodiment of the present invention.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied.

As used herein, the term “substrate” may refer to any underlying material or materials that may be used, or upon which, a device, a circuit, or a film may be formed, which is typically semiconductor wafer.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

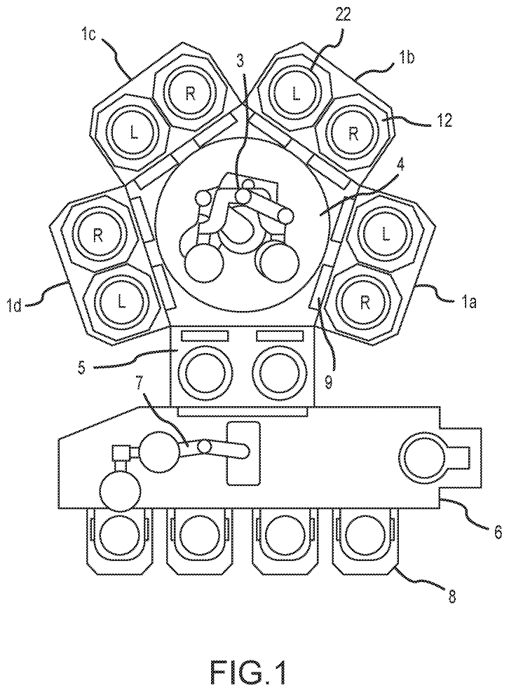

FIG. 1 is a schematic plan view of a substrate processing apparatus with dual chamber modules in an embodiment of the present invention. The substrate processing apparatus may comprise four process modules 1a, 1b, 1c, 1d (each provided with two reaction chambers 12, 22), a load lock chamber 5, and a substrate handling chamber 4 provided with back end robots 3.

In this embodiment, the substrate processing apparatus may comprise: (i) four process modules 1a-1d, each having two reaction chambers 12, 22 arranged side by side with their fronts aligned in a line; (ii) a substrate handling chamber 4 including two back end robots 3 (substrate handling robots); and (iii) a load lock chamber 5 for loading or unloading two substrates simultaneously, the load lock chamber 5 being attached to the one additional side of the substrate handling chamber 4, wherein each back end robot 3 is accessible to the load lock chamber 5. Each of the back end robots 3 have at least two end-effectors accessible to the two reaction chambers of each unit simultaneously, said substrate handling chamber 4 having a polygonal shape having four sides corresponding to and being attached to the four process modules 1a-1d, respectively, and one additional side for a load lock chamber 5, all the sides being disposed on the same plane. The interior of each reaction chamber 12, 22 and the interior of the load lock chamber 5 may be isolated from the interior of the substrate handling chamber 4 by a gate valve 9.

In some embodiments, a controller (not shown) may store software programmed to execute sequences of substrate transfer, for example. The controller may also: check the status of each process chamber; position substrates in each process chamber using sensing systems, control a gas box, and an electric box for each module; control a front end robot 7 in an equipment front end module 6 based on a distribution status of substrates stored in FOUP 8 and a load lock chamber 5; control back end robots 3; and control gate valves 9 and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of reaction chambers and process modules greater than one (e.g., 2, 3, 4, 5, 6, or 7). In FIG. 1, the apparatus has eight reaction chambers, but it may have ten or more. In some embodiments, the reactors of the modules may be any suitable reactors for processing or treating wafers, including CVD reactors (such as plasma-enhanced CVD reactors and thermal CVD reactors) or ALD reactors (such as plasma-enhanced ALD reactors and thermal ALD reactors). Typically, the reaction chambers may be plasma reactors for depositing a thin film or layer on a wafer. In some embodiments, all the modules may be of the same type having identical capabilities for treating wafers so that the unloading/loading can sequentially and regularly be timed, thereby increasing productivity or throughput. In some embodiments, the modules may have different capabilities (e.g., different treatments) but their handling times may be substantially identical.

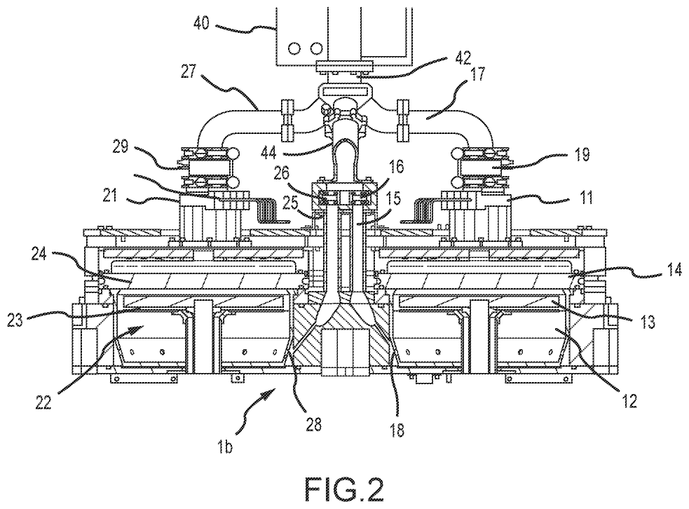

FIG. 2 is a schematic cross-sectional view of a dual chamber module in an embodiment of the present invention. In the reaction chamber 12, a shower plate 14 and a susceptor 13 may be provided, and in the reaction chamber 22, a shower plate 24 and a susceptor 23 may be provided. The susceptors 13, 23 may support a substrate and be heated by an incorporated heater or an external heater, thereby controlling a temperature of the substrate.

The shower plates 14, 24 may be constructed and arranged to face the susceptors 13, 23. The shower plates 14, 24 may be provided with a plurality of holes such a process gas is supplied to the substrate placed on the susceptor 13, 23, thereby causing the deposition of a thin film onto the substrate.

A remote plasma unit (RPU) 40 may be disposed above the reaction chambers 12, 22. A cleaning gas may be supplied to the RPU 40 from a cleaning gas source (not shown), thereby turning into gas radicals, gas ions, or both (reactive gases). The cleaning gas may be at least one of, for example, Ar, O2, NF3, C2F6, or SF6.

The cleaning gases may be introduced into the reaction chambers 12, 22 using a central cleaning gas line 42 and second cleaning gas lines 17, 27 through the showerheads 14, 24. The second cleaning gas lines 17, 27 may be arranged substantially symmetrically between the reaction chambers 12, 22 from the splitting point. A first end of the central cleaning gas line 42 may be connected to the RPU 40. The other end of the shared cleaning gas line 42 may be split into three gas lines, which are the second cleaning gas lines 17, 27 and the third cleaning gas line 44.

Each of the second cleaning gas lines 17, 27 may be provided with RPU gate valves 19, 29 and process gas lines 11, 21. The RPU gate valves 19, 29 may be closed when a process gas is being supplied to substrates through the process gas lines 11, 21 and the showerhead 14, 24, thereby preventing the cleaning gas from being mixed into the process gas.

The cleaning gas may be also introduced into lower regions of the reaction chambers 12, 22 using the central cleaning gas line 42, the third cleaning gas line 44, and first cleaning gas lines 15, 25. The first cleaning gas lines 15, 25 may be arranged substantially symmetrically between the reaction chambers 12, 22 from the splitting point. Each first cleaning gas line 15, 25 may be provided with valves 16, 26.

A controller (not shown) may be configured to control the valves 16, 26 between an open position and a closed position. The valves 16, 26 may be closed when the process gas is being supplied to substrates, thereby preventing a cross talk between the reaction chambers 12, 22.

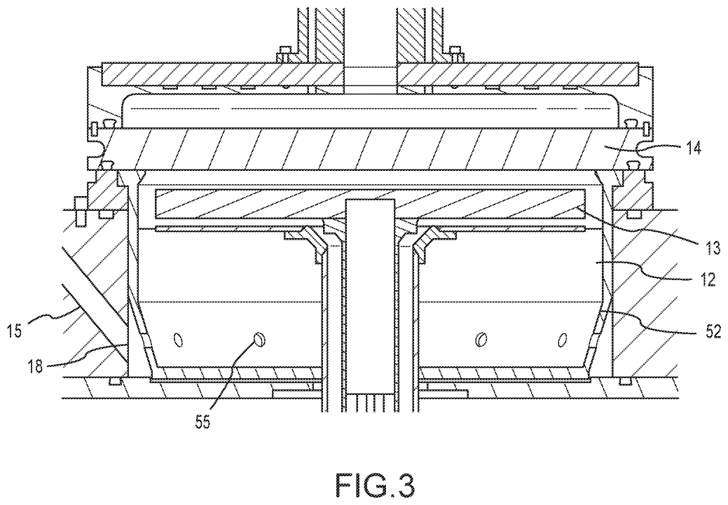

FIG. 3 is a schematic cross-sectional view of a chamber module in an embodiment of the present invention. The cleaning gas line 15 may be connected to a sidewall of the reaction chamber 12 through a cleaning gas opening 18. A chamber liner 52 may be disposed in the sidewall of the reaction chamber 12. The chamber liner 52 may have a plurality of holes 55, which are fluidly coupled to the cleaning gas opening 18. The holes 55 may be equally spaced on the chamber liner 52, thereby cleaning the reaction chamber evenly. The chamber liner may comprise Al₂O₃ or AlN.

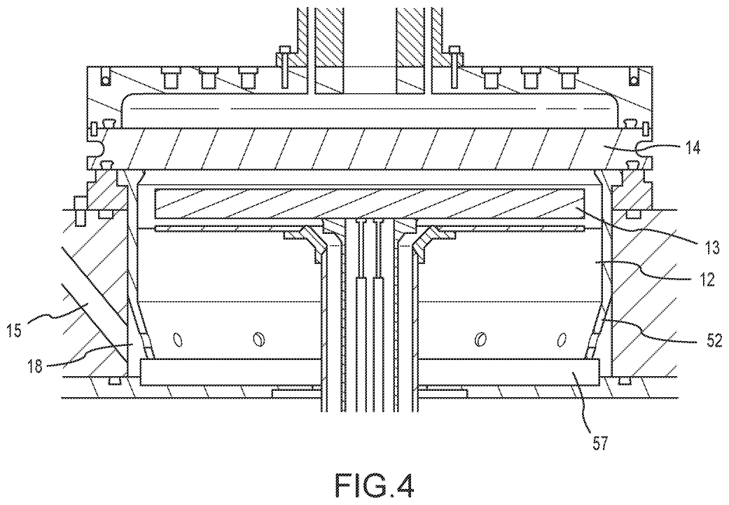

FIG. 4 is a schematic cross-sectional view of a reaction chamber in another embodiment of the present invention. Instead of the holes 55 in FIG. 3, a gap 57 may be provided between a bottom of the reaction chamber 12 and the bottom of the chamber liner 52. The distance of the gap 57 may be 0.3 mm to 20 mm.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a reaction chamber;
a remote plasma unit;
a cleaning gas lines configured to fluidly couple the remote plasma unit to the reaction chambers; and a chamber liner disposed in a sidewall of the reaction chamber;
wherein the cleaning gas line is connected to the sidewall of the reaction chamber through a cleaning gas opening;
wherein the chamber liner is provided with a plurality of holes, being fluidly coupled to the cleaning gas opening.

2. The substrate processing apparatus according to claim 1, wherein the holes are equally spaced on the chamber liner.

3. The substrate processing apparatus according to claim 1, further comprising a susceptor positioned within the reaction chamber to be constructed and arranged to support a substrate.

4. The substrate processing apparatus according to claim 2, further comprising a shower plate to be constructed and arranged to face the susceptor.

5. The substrate processing apparatus according to claim 4, further comprising a second cleaning line disposed between the remote plasma unit and the shower plate.

6. The substrate processing apparatus according to claim 5, wherein the second cleaning gas line is provided with a process gas line to supply a process gas to the reaction chamber through the shower plate.

7. A substrate processing apparatus, comprising:
a reaction chamber;
a remote plasma unit;
a cleaning gas lines configured to fluidly couple the remote plasma unit to the reaction chambers;
a chamber liner disposed in a sidewall of the reaction chamber; and
a gap provided between a bottom of the reaction chamber and a bottom of the chamber liner,
wherein the cleaning gas line is connected to the sidewall of the reaction chamber through a cleaning gas opening;
wherein the gap configured to fluidly couple the cleaning gas opening.

8. The substrate processing apparatus according to claim 7, further comprising a susceptor positioned within the reaction chamber to be constructed and arranged to support a substrate.

9. The substrate processing apparatus according to claim 8, further comprising a shower plate to be constructed and arranged to face the susceptor.

10. The substrate processing apparatus according to claim 9, further comprising a second cleaning lines disposed between the remote plasma unit and the shower plate.

11. The substrate processing apparatus according to claim 10, wherein the second cleaning gas line is provided with a process gas line to supply a process gas to the reaction chamber through the shower plate.
